(19) United States
(12) Patent Application Publication
(10) Pub. No.: US 2005/0173722 A1
(43) Pub. Date: Aug. 11, 2005

(54) SEMICONDUCTOR DEVICE AND METHOD FOR MANUFACTURING THE SAME

(75) Inventor: Takuji TANAKA, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 10/604,891

(22) Filed: Aug. 25, 2003

(30) Foreign Application Priority Data
Aug. 30, 2002 (JP) 2002-255473

(51) Int. Cl. H01L 33/00

(52) U.S. Cl. 257/100

(57) ABSTRACT

A MOS transistor has a gate electrode formed on a semiconductor substrate via a gate insulation film and a source and a drain formed on both sides of the gate electrode, wherein, with sidewall films each consisting of two layers (a thin first film and a second film for covering the first film), a lower part of the first film, that is, only a side lower portion of the gate electrode becomes a local low permittivity region to be filled in with a low permittivity material, and then the second film is formed to cover the low permittivity material.

### CROSS REFERENCE TO RELATED APPLICATIONS

This application is based upon and claims the benefit of priority from the prior Japanese Patent Application No. 2002-255473, filed on Aug. 30, 2002, the entire contents of which are incorporated herein by reference.

### FIELD OF THE INVENTION

The present invention relates to a semiconductor device such as a MOS transistor having a gate, a source, and a drain, and a method for manufacturing the same.

### DESCRIPTION OF THE RELATED ART

Recently, along with progress in high integration and high performance for a semiconductor device, various demands for the semiconductor device have been still more increasing. Among them, strong demands are to make even thinner films of a gate insulation film and a sidewall insulation film. This causes to increase fringe capacitance, that is, parasitic capacitance generated mainly between a gate electrode and a semiconductor substrate, which is seen as a problem. As a conventional art to attempt reducing this fringe capacitance, for example, Japanese Patent Laid-open No. Hei 9-246544 discloses technology to provide a cavity on a whole side surface between the gate electrode and the gate insulation film and the sidewall insulation film.

The above-described conventional art is effective to a great extent in reducing the fringe capacitance, but then in the first place, forming the cavity is not a simple task, and further an impurity introduced into the gate electrode in order to facilitate threshold voltage control tends to escape from the cavity in heat treatment processes thereafter.

### SUMMARY OF THE INVENTION

An object of the present invention is to provide such a semiconductor device as to reduce fringe capacitance in the most effective manner and to deter an escape of the above-mentioned impurity as much as possible, as well as to have a relatively simple manufacturing, and to provide a method for manufacturing the same.

The inventor reaches various aspects of the present invention described below through a committed consideration.

This invention aims at a semiconductor device including a gate, a source, and a drain, and a method for manufacturing the same.

A semiconductor device according to this invention has: a sidewall film covering a side surface of the gate; and a low permittivity region locally provided only at a lower portion of the side surface of the gate with the low permittivity region being covered by the sidewall film. The low permittivity region is preferably filled with a predetermined low permittivity material or left as a cavity.

A method for manufacturing the semiconductor device according to this invention includes the steps of: forming a thin first film covering a side surface of the gate; removing only a lower portion of the first film; locally filling only a lower portion of the side surface of the gate, at which the first film is removed, with a lower permittivity material as compared to the first film; and forming a second film on the first film to cover the low permittivity material.

A method for manufacturing the semiconductor device according to this invention includes the steps of: forming a thin first film covering a side surface of the gate; removing only a lower portion of the first film; and forming a second film on the first film with low step coverage, to thereby form a cavity at a lower portion of the side surface of the gate.

A method for manufacturing the semiconductor device according to this invention includes the steps of: removing a part of a side wall lower portion of the gate to process it into a notched shape; locally filling only the part with a lower permittivity material as compared to the first film; and forming a sidewall film on a side surface of the gate to cover the low permittivity material.

A method for manufacturing the semiconductor device according to this invention includes the steps of: removing a part of a side wall lower portion of the gate to process it into a notched shape; and forming a sidewall film on a side surface of the gate with low step coverage to such an extent as not to fill in the part, to thereby form a cavity at a lower portion of the side surface of the gate.

### BRIEF DESCRIPTION OF THE DRAWINGS

FIG. 1 is a schematic sectional view to describe a first aspect of this invention;

FIG. 2 is a schematic sectional view to describe a second aspect of this invention;

FIG. 3 is a schematic sectional view to describe a third aspect of this invention;

FIG. 4 is a schematic sectional view to describe a fourth aspect of this invention;

FIGS. 5A to 5G are schematic sectional views showing, in a process order, a method for manufacturing a MOS transistor relating to a first embodiment;

FIG. 6A to 6F are schematic sectional views showing, in a process order, a method for manufacturing a MOS transistor relating to a second embodiment;

FIG. 7A to 7F are schematic sectional views showing, in a process order, a method for manufacturing a MOS transistor relating to a third embodiment;

FIG. 8A to 8E are schematic sectional views showing, in a process order, a method for manufacturing a MOS transistor relating to a fourth embodiment, and

FIG. 9 is a characteristic chart showing the relation between height of a low permittivity region (cavity) and fringe capacitance in the MOS transistor relating to the second embodiment.

### DETAILED DESCRIPTION OF THE PREFERRED EMBODIMENTS

Main Points of the Present Invention

In an attempt to reduce fringe capacitance, the inventor of the present invention adds a point of deterring an escape of the above-mentioned impurity and after consideration thereof, the inventor has reached such an idea to form a required minimum local low permittivity region only at a portion being the most effective in reducing the fringe capacitance. Since the fringe capacitance is parasitic capacitance generated mainly between a gate electrode end and a semiconductor substrate, the low permittivity region may be formed at a side lower portion of the gate electrode, that is, the most responsible portion for generating this parasitic capacitance.

First Aspect

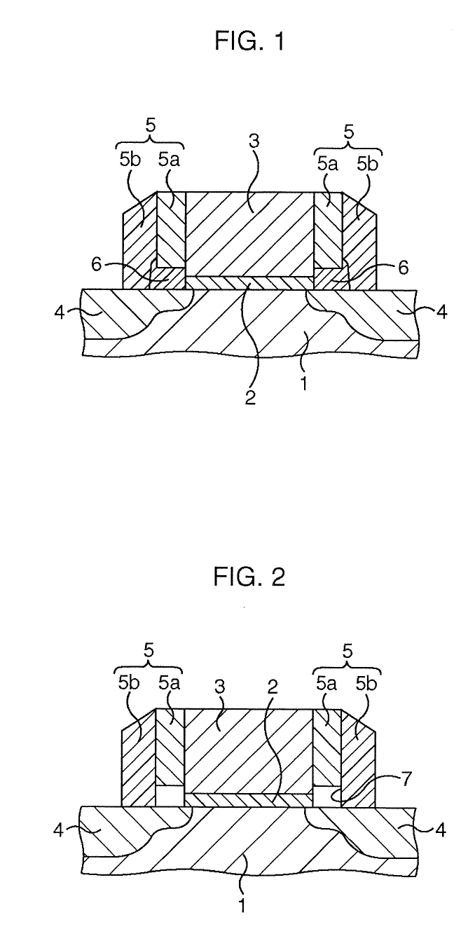

Here, as shown in FIG. 1, a MOS transistor has a gate electrode 3 formed on a semiconductor substrate 1 via a gate insulation film 2, and a source 4 and a drain 4 formed on both sides of the gate electrode 3, wherein, with sidewall films 5 each consisting of two layers (a thin first film 5a and a second film 5b for covering the first film 5a), a lower part of the first film 5a, that is, only a side lower portion of the gate electrode 3 becomes a local low permittivity region to be filled in with a low permittivity material 6, and then the second film 5b is formed to cover the low permittivity material 6.

Second Aspect

Here, as shown in FIG. 2, in a MOS transistor similar to that in FIG. 1, with sidewall films 5 each consisting of two layers (a thin first film 5a and a second film 5b for covering the first film 5a), the first film 5a is formed only at a side upper portion of the gate electrode 3, while only a side lower portion of the gate electrode 3 becomes a low permittivity region. Then, the second film 5b is formed with low step coverage so as not to fill in the region, to thereby form a local cavity 7 surrounded by the sidewall films 5.

Third Aspect

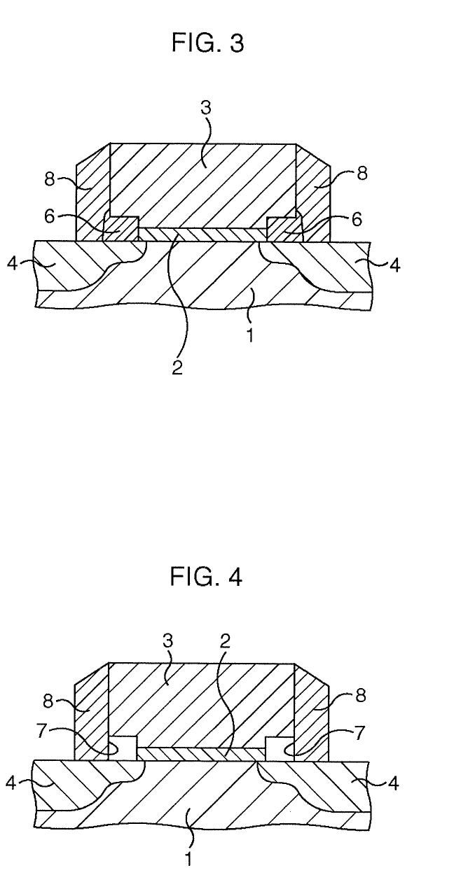

Here, as shown in FIG. 3, in a MOS transistor similar to that in FIG. 1, a part of side wall lower portions (and a gate insulation film 2) of a gate electrode 3 is removed by etching to make it notch-shaped. Then, this portion becomes a local low permittivity region to be filled in with a low permittivity material 6, and then sidewall films 8 are formed to surround it.

Fourth Aspect

Here, as shown in FIG. 4, in a MOS transistor similar to that in FIG. 1, a part of side wall lower portions (and a gate insulation film 2) of a gate electrode 3 is removed by etching to make it notch-shaped. Then, this portion becomes a local low permittivity region and sidewall films 8 are formed with low step coverage so as not to fill in the local low permittivity region, to thereby form a local cavity 7 surrounded by the sidewall films 8.

Japanese Patent Laid-open No. Hei 4-152535 discloses a semiconductor device composed of a high dielectric film at a lower portion of sidewall films and a low dielectric film at an upper portion thereof. An object thereof is to attempt having even lower electric field at an LDD part and reducing the parasitic capacitance between the gate and wiring. Therefore, the disclosed invention totally differs from the present invention not only in its structure, but also in its objects and effect.

Specific Various Embodiments

Based on the contents of the above-described main points of this invention, various preferred embodiments, to which this invention is applied, are described in detail with reference to the drawings.

First Embodiment

This embodiment discloses a structure of a semiconductor device that has a MOS transistor structure having a gate electrode, a source, and a drain, and a method for manufacturing the same. Here, the MOS transistor structure is explained together with its manufacturing process for convenience.

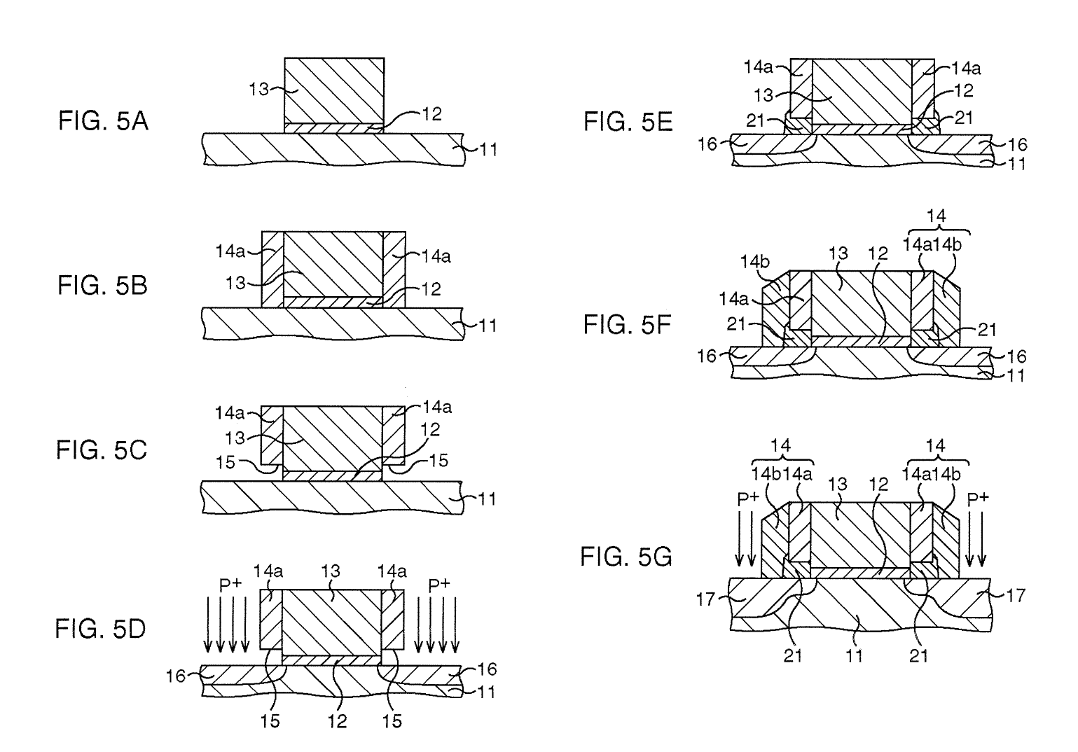

FIGS. 5A to 5G are schematic sectional views showing, in a process order, a method for manufacturing the MOS transistor relating to this embodiment.

First, as shown in FIG. 5A, a polycrystalline silicon film (not shown) is deposited on, for example, a p-type silicon semiconductor substrate 11 via a gate insulation film 12 by a CVD method or the like, and patterning of the polycrystalline silicon film and the gate insulation film 12 into an electrode shape causes to form a gate electrode 13.

Next, as shown in FIG. 5B, for example, a silicon oxide film (not shown) is deposited on the semiconductor device 11 by the CVD method or the like to cover the gate electrode 13, and full anisotropic etching (etch back) of this silicon oxide film causes to form thin first films 14a only on side surfaces of the gate electrode 13 and the gate insulation film 12.

Next, as shown in FIG. 5C, only lower portions of the first films 14a are selectively removed by, for example, wet etching, to expose surfaces on side lower portions of the gate electrode 13. Here, the exposed side lower portions of the gate electrode 13 become low permittivity regions 15.

Next, as shown in FIG. 5D, ion implantation of an n-type impurity such as phosphorus (P) is performed using the gate electrode 13 and the first films 14a as masks, to form a pair of extension regions 16 on a surface layer of the semiconductor substrate 11.

Next, as shown in FIG. 5E, a low permittivity material 21 is formed on the gate electrode 13 with the low permittivity regions 15 being filled in, and etching (for example, etch back) thereof causes to leave the low permittivity materials 21 only in the low permittivity regions 15. Here, such low permittivity materials are used for the low permittivity material 21 as a SiOF, an arylether based organic low permittivity material, a fluorocarbon based low permittivity material, a hydrogen silses quioxane based low permittivity material, a hydromethyl silses quioxane based low permittivity material, a porous quioxane based low permittivity material, a porous allylether based low permittivity material, or the like.

Next, as shown in FIG. 5F, for example, a silicon nitride film (not shown) is deposited by the CVD method or the like to cover the gate electrode 13, and thereafter the full anisotropic etching (etch back) of this silicon nitride film causes to form second films 14b that cover side surfaces of the first films 14a and the low permittivity regions 15 filled with the low permittivity material 21. Thereby, sidewall films 14 are formed to surround the low permittivity regions 15, the sidewall films 14 each consisting of the first film 14a and the second film 14b.

Next, as shown in FIG. 5G, the ion implantation of the n-type impurity such as phosphorus (P) is performed using the gate electrode 13 and the sidewall films 14 as masks, and a source 17 and a drain 17 are formed on the surface layer of the semiconductor substrate 11 to partially overlap with the extension regions 16.

Thereafter, interlayer insulation films, contact holes, various wiring layers, and the like are formed to bring the MOS transistor to completion.

Second Embodiment

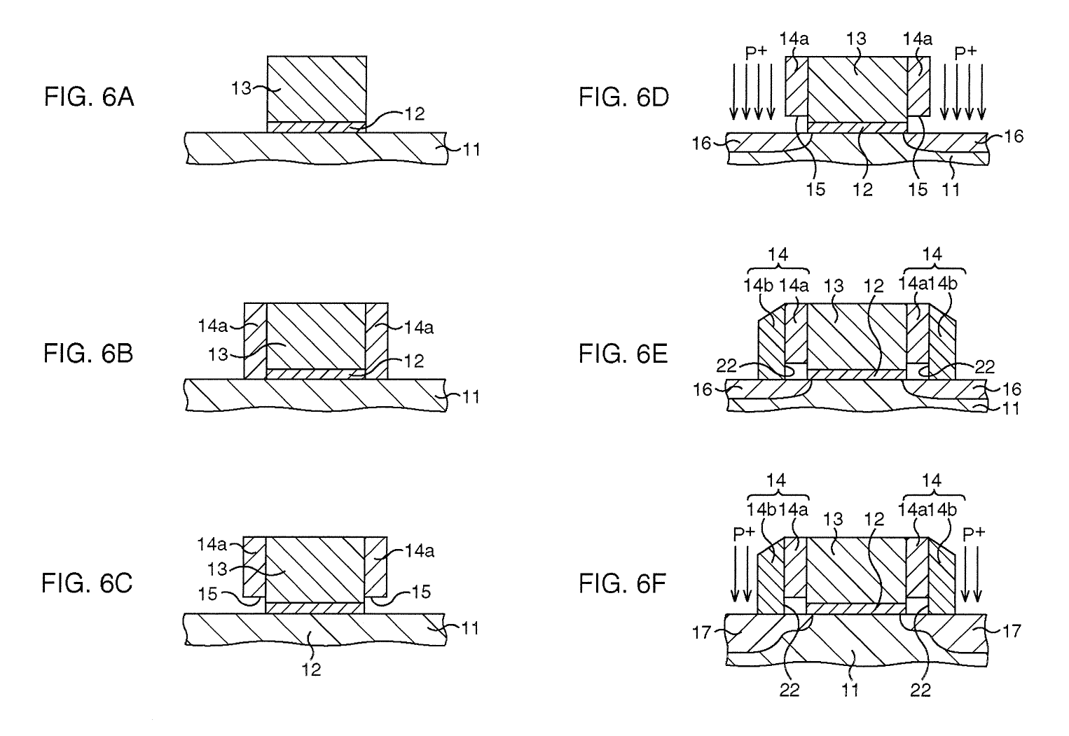

FIGS. 6A to 6F are schematic sectional views showing, in a process order, a method for manufacturing a MOS transistor relating to this embodiment.

First, as shown in FIG. 6A, a polycrystalline silicon film (not shown) is deposited on, for example, a p-type silicon semiconductor substrate 11 via a gate insulation film 12 by a CVD method or the like, and patterning of the polycrystalline silicon film and the gate insulation film 12 into an electrode shape causes to form a gate electrode 13.

Next, as shown in FIG. 6B, for example, a silicon oxide film (not shown) is deposited on the semiconductor device 11 by the CVD method or the like to cover the gate electrode 13, and full anisotropic etching (etch back) of this silicon oxide film causes to form thin first films 14a only on side surfaces of the gate electrode 13 and the gate insulation film 12.

Next, as shown in FIG. 6C, only lower portions of the first films 14a are selectively removed by, for example, wet etching, to expose surfaces on side lower portions of the gate electrode 13. Here, the exposed side lower portions of the gate electrode 13 become low permittivity regions 15.

Next, as shown in FIG. 6D, ion implantation of an n-type impurity such as phosphorus (P) is performed using the gate electrode 13 and the first films 14a as masks, to form a pair of extension regions 16 on a surface layer of the semiconductor substrate 11.

Next, a silicon oxide film (not shown) covering the gate electrode 13 and the first films 14a is formed with low step coverage (low in step coverage) to such an extent as not to fill in the low permittivity regions 15. This silicon oxide film may be formed by a low temperature oxidation (LTO) method or a sputtering method. For example, it is formed under the condition of low temperature of 400 by inputting high frequency (RF) power of 400 W with the use of a parallel plate plasma CVD apparatus. Then, as shown in FIG. 6E, the full anisotropic etching (etch back) of this silicon oxide film causes to form second films 14b that cover the low permittivity regions 15. Thereby, sidewalls 14 are formed to surround the low permittivity regions 15, the sidewalls 14 covering the first films 14a to have a cavity 22 with the first film 14a.

Next, as shown in FIG. 6F, the ion implantation of the n-type impurity such as phosphorus (P) is performed using the gate electrode 13 and the sidewall films 14 as masks, and a source 17 and a drain 17 are formed on the surface layer of the semiconductor substrate 11 to partially overlap with the extension regions 16.

Thereafter, interlayer insulation films, contact holes, various wiring layers, and the like are formed to bring the MOS transistor to completion.

Third Embodiment

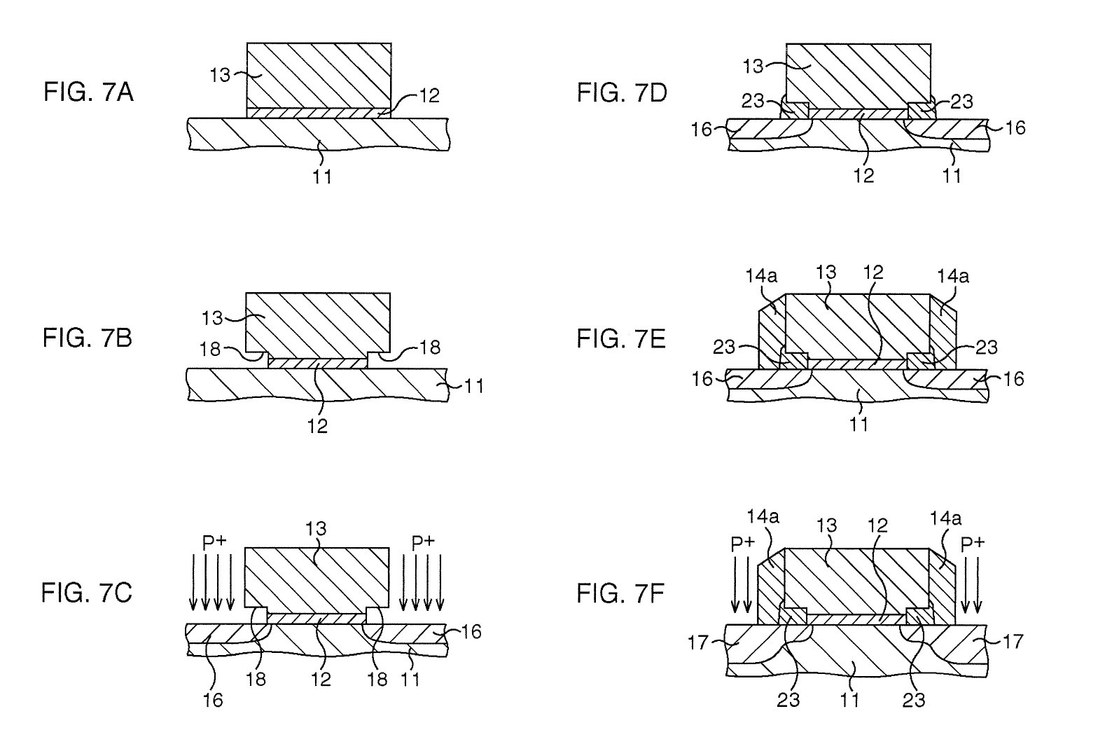

FIGS. 7A to 7F are schematic sectional views showing, in a process order, a method for manufacturing a MOS transistor relating to this embodiment.

First, as shown in FIG. 7A, a polycrystalline silicon film (not shown) is deposited on, for example, a p-type silicon semiconductor substrate 11 via a gate insulation film 12 by a CVD method or the like, and patterning of the polycrystalline silicon film and the gate insulation film 12 into an electrode shape causes to form a gate electrode 13.

Next, as shown in FIG. 7B, side wall lower portions of the gate electrode 13 and a part of the gate insulation film 12 are removed by etching to make it notch-shaped. The notch sections become low permittivity regions 18.

Next, as shown in FIG. 7C, ion implantation of an n-type impurity such as phosphorus (P) is performed using the gate electrode 13 as a mask, to form a pair of extension regions 16 on a surface layer of the semiconductor substrate 11.

Next, as shown in FIG. 7D, a low permittivity material 23 is formed on the gate electrode 13 with the low permittivity regions 18 being filled in, and etching (for example, etch back) thereof causes to leave the low permittivity materials 23 only in the low permittivity regions 18. Here, such low permittivity materials are used for the low permittivity material 23 as a SiOF, an arylether based organic low permittivity material, a fluorocarbon based low permittivity material, a hydrogen silses quioxane based low permittivity material, a hydromethyl silses quioxane based low permittivity material, a porous quioxane based low permittivity material, a porous allylether based low permittivity material, or the like.

Next, as shown in FIG. 7E, for example, a silicon nitride film (not shown) is deposited by the CVD method or the like to cover the gate electrode 13, and thereafter the full anisotropic etching (etch back) of this silicon nitride film causes to form sidewall films 19 that cover side surfaces of the gate electrode 13 and the low permittivity regions 18 filled with the low permittivity material 23.

Next, as shown in FIG. 7F, the ion implantation of the n-type impurity such as phosphorus (P) is performed using the gate electrode 13 and the sidewall films 19 as masks, and a source 17 and a drain 17 are formed on the surface layer of the semiconductor substrate 11 to partially overlap with the extension regions 16.

Thereafter, interlayer insulation films, contact holes, various wiring layers, and the like are formed to bring the MOS transistor to completion.

Fourth Embodiment

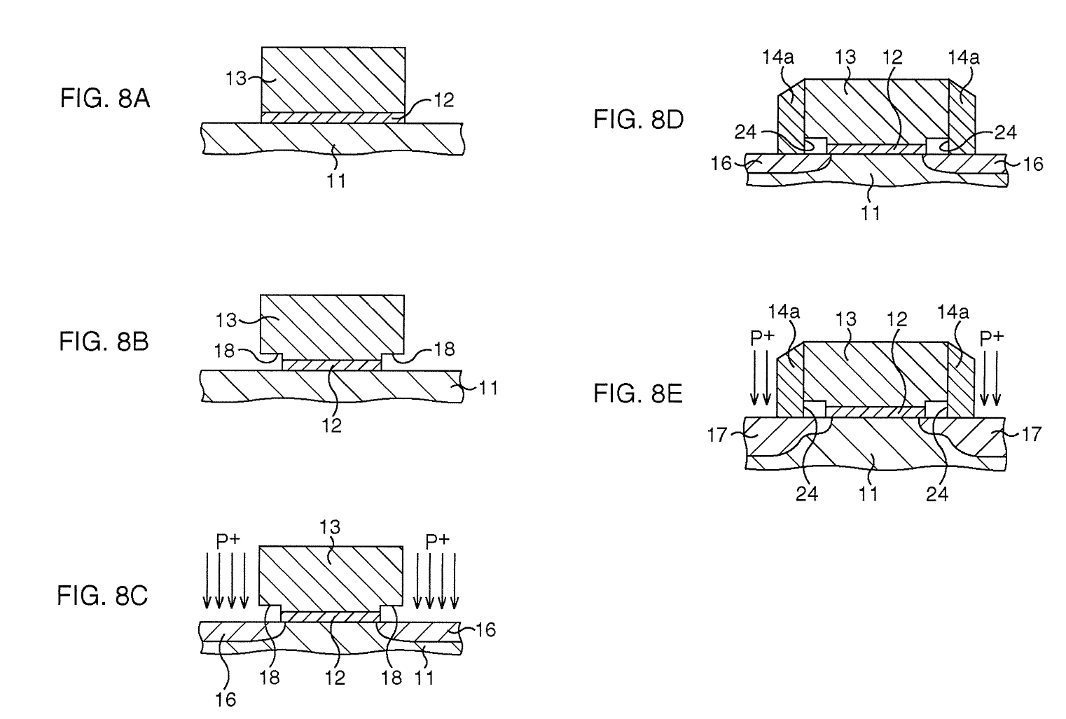

FIGS. 8A to 8E are schematic sectional views showing, in a process order, a method for manufacturing a MOS transistor relating to this embodiment.

First, as shown in FIG. 8A, a polycrystalline silicon film (not shown) is deposited on, for example, a p-type silicon semiconductor substrate 11 via a gate insulation film 12 by a CVD method or the like, and patterning of the polycrystalline silicon film and the gate insulation film 12 into an electrode shape causes to form a gate electrode 13.

Next, as shown in FIG. 8B, side wall lower portions of the gate electrode 13 and a part of the gate insulation film 12 are removed by etching to make it notch-shaped. The notch sections become low permittivity regions 18.

Next, as shown in FIG. 8C, ion implantation of an n-type impurity such as phosphorus (P) is performed using the gate electrode 13 as a mask, to form a pair of extension regions 16 on a surface layer of the semiconductor substrate 11.

Next, as shown in FIG. 8D, a silicon oxide film (not shown) covering the gate electrode 13 and first films 14a is formed with low step coverage (low in step coverage) to such an extent as not to fill in the low permittivity regions 18. This silicon oxide film may be formed by a low temperature oxidation (LTO) method or a sputtering method. For example, it is formed under the condition of low temperature of 400 by inputting high frequency (RF) power of 400 W with the use of a parallel plate plasma CVD apparatus. Then, full anisotropic etching (etch back) of this silicon oxide film causes to form sidewall films 19 that surround the low permittivity regions 18 being left as a cavity 24.

Next, as shown in FIG. 8E, the ion implantation of the n-type impurity such as phosphorus (P) is performed using the gate electrode 13 and the sidewall films 19 as masks, and a source 17 and a drain 17 are formed on the surface layer of the semiconductor substrate 11 to partially overlap with the extension regions 16.

Thereafter, interlayer insulation films, contact holes, various wiring layers, and the like are formed to bring the MOS transistor to completion.

Although the first to fourth embodiments exemplify a case to form a source and a drain in an LDD structure including an extension region, this invention is also applicable to a MOS transistor having only a single drain structure. In addition, this invention is not limited to a bulk-type MOS transistor and is also applicable to a MIS transistor, a SOI-type MOS transistor, a double gate type MOS transistor, and the like. Further, the low permittivity region may be provided not on both sides of the source and the drain but only on one side thereof.

Fringe Capacitance of MOS Transistor in the Present Embodiments

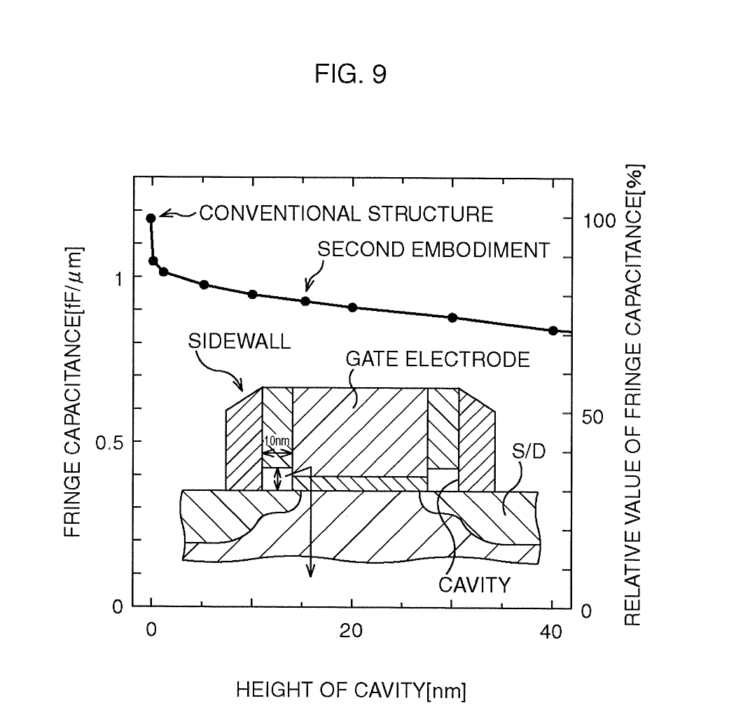

Here, taking the MOS transistor in the second embodiment (second aspect) for example, the relation between height of the low permittivity region (cavity) (which substantially corresponds to cavity size when width thereof is unified to a steady value (for example, 10 nm) and fringe capacitance is examined. FIG. 9 shows a result of this simulation experiment.

In FIG. 9, the horizontal axis designates the height of the cavity, the left vertical axis designates the fringe capacitance, and the right vertical axis designates a relative value of fringe capacitance normalized by a value of a conventional device structure in which the cavity does not exist. As shown in the chart, locally forming a cavity of about 15 nm in height simply enables to reduce the fringe capacitance by 20 or more as compared to that of the conventional structure in which the cavity does not exist. Further, the similar simulation indicates that locally forming a microcavity having only 5 nm in height and 5 nm in width simply enables to reduce the fringe capacitance by 10 or more as compared to that of the conventional structure in which the cavity does not exist. In this case, even if the height of the cavity is further increased, great decrease in the fringe capacitance cannot be observed.

Therefore, as in this embodiment, the portion (side lower portion of the gate electrode) being the most effective in reducing the fringe capacitance is determined and then a required minimum cavity is locally formed in this portion, so that the fringe capacitance can be fully reduced with an impurity introduced in the gate electrode not escaping from the cavity in the heat treatment processes thereafter, which differs from the invention of Japanese Patent Laid-open No. Hei 9-246544. Note that this effect can be seen not only in the second embodiment but also in the first, third, and fourth embodiments.

According to the present invention, such a semiconductor device is realized as to reduce the fringe capacitance in the most effective manner and to deter an escape of the above-mentioned impurity as much as possible, as well as to have a relatively simple manufacturing.

The present embodiments are to be considered in all respects as illustrative and no restrictive, and all changes which come within the meaning and range of equivalency of the claims are therefore intended to be embraced therein. The invention may be embodied in other specific forms without departing from the spirit or essential characteristics thereof.

Hereinafter, various aspects of this invention are described as claims.

1. A semiconductor device including a gate having a gate insulation film and a gate electrode, a source, and a drain, said semiconductor device comprising:
a sidewall film covering a side surface of said gate; and
a low permittivity region locally provided at a lower portion of the side surface of said gate with the low permittivity region being covered by said sidewall film,
wherein said gate insulation film and a lower end of said gate electrode have a same width as each other.

2. The semiconductor device according to claim 1, wherein said low permittivity region is made of a lower permittivity material as compared to said sidewall film.

3. The semiconductor device according to claim 2, wherein said sidewall film includes
a first film directly formed at an upper portion of said side surface of said gate, and
a second film formed on said first film to cover said low permittivity region directly formed at the lower portion of the side surface of said gate.

4. The semiconductor device according to claim 1, wherein said low permittivity region is a cavity.

5. The semiconductor device according to claim 4, wherein said sidewall film includes
a first film directly formed only at an upper portion of said side surface of said gate, and
a third film covering said first film to form the cavity only at a lower portion of said side surface.

6. The semiconductor device according to claim 1, wherein a part of a side wall lower portion of said gate is removed to have said low permittivity region formed into a notched shape.

7. The semiconductor device according to claim 6, wherein said low permittivity region is made of a lower permittivity material as compared to said sidewall film.

8. The semiconductor device according to claim 6, wherein said low permittivity region is a cavity.

9. A method for manufacturing a semiconductor device including a gate, a source, and a drain, said method comprising the steps of:
forming a thin first film covering a side surface of said gate;
removing only a lower portion of said first film;
locally filling only a lower portion of the side surface of said gate, at which said first film is removed, with a low permittivity material; and
forming a second film on said first film to cover said low permittivity material.

10. A method for manufacturing a semiconductor device including a gate, a source, and a drain, said method comprising the steps of:
forming a thin first film covering a side surface of said gate;
removing only a lower portion of said first film; and
forming a second film on said first film with low step coverage, to thereby form a cavity at a lower portion of the side surface of said gate.

11. A method for manufacturing a semiconductor device including a gate, a source, and a drain, said method comprising the steps of:
removing a part of a side wall lower portion of said gate to process it into a notched shape;
locally filling only said part with a low permittivity material; and
forming a sidewall film on a side surface of said gate to cover said low permittivity material.

12. A method for manufacturing a semiconductor device including a gate, a source, and a drain, said method comprising the steps of:
removing a part of a side wall lower portion of said gate to process it into a notch shape; and
forming a sidewall film on a side surface of said gate with low step coverage to such an extent as not to fill in said part, to thereby form a cavity at a lower portion of the side surface of said gate.
